(19) United States
(12) Patent Application Publication
(10) Pub. No.: US 2003/0237032 A1
(43) Pub. Date: Dec. 25, 2003

(54) Method for electronically testing memory modules

(76) Inventors: Frank Adler, Munchen (DE); Markus Forste, Ottobrunn (DE); Frank Thiele, Munchen (DE)

Correspondence Address: LERNER AND GREENBERG, P.A., POST OFFICE BOX 2480, HOLLYWOOD, FL, 33022-2480, US

(21) Appl. No.: 10/395,454

(22) Filed: Mar. 24, 2003

(30) Foreign Application Priority Data
Mar. 22, 2002 (DE) 102 13 009.4

(51) Int. Cl. G11C 29/00

(52) U.S. Cl. 714/718

(57) ABSTRACT

In the case of an inventive method for electronically testing memory modules, a memory module to be tested is connected to a test computer system. A computer system configuration file and test information for the memory module to be tested are then electronically read into the computer system. Next, the memory module is electronically tested by step-by-step automatically processing the test steps in at least one functional test. The test results are electronically stored in at least one result file step by step and are automatically evaluated. Error information is electronically stored in at least one statistic file and is output.

### BACKGROUND OF THE INVENTION

1. Field of the Invention

The invention relates to a method for electronically testing memory modules.

Memory modules, particularly DIMMs (Dual Inline Memory Modules), small outline DIMMs (SO-DIMMs), DDR-X DIMMs (Double Data Rate (X=I, II) Dual Inline Memory Modules) and RIMMs (Rambus Inline Memory Modules) are used in personal computers, workstations, Notebooks and servers. These execute a large number of different applications that require different operating modes for the memory modules and generate a great diversity of data patterns.

The data patterns produced cannot be tested exhaustively on account of the great storage depth of up to 128 Mbits per I/O pin, which exists in ordinary memory modules. To obtain a picture of the reliability of memory modules and to perform analyses on memory modules, memory test programs are therefore executed when these memory modules are manufactured. Various memory test programs are available, particularly in the form of freewear. To execute such memory test programs, which normally run on the DOS operating system, at least one memory module to be tested is connected to a computer system or to a test platform.

Published German Patent Application DE 100 34 900 A1 discloses a system for testing fast synchronous digital circuits, particularly semiconductor chips, in which test signals such as test data, control, address and clock signals are transmitted, based on signal conditions prescribed by a test unit, to a circuit that will be tested. Response signals generated for the supplied test signals are evaluated.

Published German Patent Application DE 100 34 855 A1 discloses a system for testing fast integrated digital circuits, particularly semiconductor chips, e.g. SDRAMs (Synchronous Dynamic Random, Access Memories), in which test signals such as test data, control, address and clock signals are prescribed by a test unit, are supplied to the chip being tested and are routed to the evaluation section by the chip under test on the basis of result signals generated for the test signals.

A drawback of such memory test programs is that they cannot be used, or can be used only with difficulty, for memory tests during the manufacture of memory modules. This is because they use different protocol forms to present the test results, are frequently difficult to use, and take into account little information from the test platform used. In addition, the susceptibility to error is very high for test inputs and it is not possible to use a simple key to decide how different types of memory modules are tested on different test platforms using various system boards. Furthermore, the memory test programs frequently do not store the test results as comprehensive information in a database. In addition, the logged information about the test platform and about the test details, for example, the test cycles, is incomplete to a degree. Also, evaluation of the test results is often not automated but rather is done manually by a test engineer. This is very complex.

The manufacture of memory modules often requires that a plurality of different memory test programs for a memory module be executed in succession or approximately simultaneously. This is almost impossible in a reasonably short time frame with a feasible level of involvement. The increasing diversity of products and platforms for DIMMs and RIMMs means that successive execution of a plurality of such memory test programs is no longer a feasible solution.

### SUMMARY OF THE INVENTION

It is accordingly an object of the invention to provide a method for testing memory modules, which overcomes the above-mentioned disadvantages of the prior art methods of this general type.

In particular, it is an object of the invention to provide a method for testing memory modules on a computer system reliably and comprehensively.

With the foregoing and other objects in view there is provided, in accordance with the invention, a method for electronically testing one or more memory modules. The method includes steps of: detachably connecting the one or more memory modules to a computer system; electronically reading a computer system configuration file into the computer system; for each one of the one or more memory modules connected to the computer system, inputting a respective memory module identifier into the computer system; electronically comparing a number of the one or more memory modules connected to the computer system with a number of memory module identifiers that have been input; electronically reading test information for the one or more memory modules into the computer system from at least one test sequence configuration file; successively and automatically processing test steps in at least one functional test to electronically test the one or more memory modules with the computer system; successively, electronically storing test results in at least one result file; automatically evaluating the test results; and if at least one of the one or more memory modules has errors, then electronically storing error information in at least one statistic file, outputting the error information, and identifying the one or more memory modules that has errors.

In accordance with an added feature of the invention, after the step of electronically reading the test information, inputting production-related data into the computer system for each of the one or more memory modules.

In accordance with an additional feature of the invention, the production-related data are batch numbers.

With the foregoing and other objects in view there is provided, in accordance with the invention, a computer-readable medium having computer-executable instructions for performing a method including steps of: electronically reading a computer system configuration file into a computer system; for each of one or more memory modules detachably connected to the computer system, inputting a respective memory module identifier into the computer system; electronically comparing a number of the one or more memory modules connected to the computer system with a number of memory module identifiers that have been input; electronically reading test information for the one or more memory modules into the computer system from at least one test sequence configuration file; successively and automatically processing test steps in at least one functional test to electronically test the one or more memory modules with the computer system; successively, electronically storing test results in at least one result file; automatically evaluating the test results; and if at least one of the one or more memory modules has errors, then electronically storing error information in at least one statistic file, outputting the error information, and identifying the one or more memory modules that has errors.

In accordance with yet an added feature of the invention, the computer-readable medium is a storage medium.

In accordance with yet an additional feature of the invention, the computer-readable medium is a computer memory.

In accordance with yet another feature of the invention, the computer-readable medium is a direct access memory.

In accordance with yet a further feature of the invention, the computer-readable medium is an electric carrier signal.

With the foregoing and other objects in view there is also provided, in accordance with the invention, a method including a step of downloading a set of computer-executable instructions from an electronic data network onto a computer connected to the data network. The computer-executable instructions that have been downloaded are for performing a method including steps of: electronically reading a computer system configuration file into a computer system, for each of one or more memory modules detachably connected to the computer system, inputting a respective memory module identifier into the computer system, electronically comparing a number of the one or more memory modules connected to the computer system with a number of memory module identifiers that have been input, electronically reading test information for the one or more memory modules into the computer system from at least one test sequence configuration file, successively and automatically processing test steps in at least one functional test to electronically test the one or more memory modules with the computer system, successively, electronically storing test results in at least one result file, automatically evaluating the test results, and if at least one of the one or more memory modules has errors, then electronically storing error information in at least one statistic file, outputting the error information, and identifying the one or more memory modules that has errors.

In accordance with a further added feature of the invention, the electronic data network is an Internet.

The inventive method for electronically testing memory modules is carried out on a computer system or on a test platform that is electrically connected to a memory module or to a plurality of memory modules. This can involve using a test module that is connected to the computer system and can be equipped with a memory module or with a plurality of memory modules.

Before the inventive method is carried out, all of the test and auxiliary programs to be executed are stored on an area of the hard disk memory in the computer system, particularly in a standard directory. The computer system is then configured, which needs to be done only once and is implemented by processing a computer system configuration file. This preferably involves providing a unique name for a respective computer system, preferably including a letter and two I numbers. The name of the motherboard and that of the chipset likewise needs to be aligned in the computer system configuration file based on the motherboard's specification. A counter concomitantly counting the number of test passes is set to the value zero.

In the first method step of the inventive method, at least one memory module to be tested is connected to the computer system. This step can be performed by inserting one or more memory modules into such a test module. An interface program in accordance with the invention is now started on the computer system. This can be done manually by a user or automatically.

Next, a computer system configuration file stored in a hard disk memory in the computer system is electronically read into the computer system or into a main memory area of the computer system. Such a computer system configuration file includes information about the name of the computer system, about the motherboard provided on the computer system, about the chipset with which the computer system is equipped, and about the number of test passes performed on the computer system.

In the next inventive method step, a user inputs a respective memory module identifier for each memory module connected to the computer system into the computer system using an input medium, for example, using a keyboard or using a mouse. Such a memory module identifier corresponds to the respective type designation of the memory module to be tested and includes a multi-element character string. Alternatively, the number of inserted memory modules to be tested can be recorded by using a separate user input.

Next, an electronic check is performed to determine whether the number of memory modules connected to the computer system matches the number of memory modules which has come from the user input. If this is the case, the inventive method continues by electronically reading in the test information for the memory module to be tested or for the memory modules to be tested from at least one test sequence configuration file.

If the number of memory modules connected to the computer system differs from the number obtained from the user input, an output appears on an output unit, particularly on a screen in the computer system. This output shows the memory configuration which the computer system's chipset has recognized. In addition, this output asks the user to check the memory modules.

In this case, the inventive method needs to be restarted in order to be able to perform a new memory check using the chipset. The idea behind this additional control mechanism is that a faulty memory module or a memory module with connection problems which is not recognized by the computer system's chipset could be connected to the computer system. In such a case, the inventive method tests only the other memory modules and, if all the other memory modules are free of error, generates a message stating that the memory modules have passed the memory test without error, even though a faulty memory module is connected. The inventive, additional control mechanism advantageously avoids such problems.

In the next method step, test information for the memory module which is to be tested or for the memory modules which are to be tested is electronically read into the computer system. In this case, this test information is read in from at least one test sequence configuration file stored in a hard disk memory in the computer system. This test information contains, for different memory modules, the respective information about which functional tests are being performed. In addition, the test information includes further method steps that are to be performed, for example, checking and/or changing memory-module specific settings.

In the next method step, the memory module or the memory modules is/are electronically tested by the computer system. This involves sequentially processing the functional tests associated with the respective memory module in the test sequence configuration file and processing supplementary and auxiliary programs. The functional tests involve using, in particular, memory tests that write data to memory modules, read them out again, and compare them. In addition, a large number of additionally executable auxiliary programs can be executed. Such auxiliary programs allow, by way of example, serial numbers or memory allocations to be requested, timings for the memory chips to be altered, refresh rates to be changed and driver powers to be varied. After every test step, the test results are automatically stored in at least one result file and are automatically evaluated.

The result file has a standard data format with precisely defined contents, namely information about the motherboard and the chipset in the computer system and about the type designation for the tested memory module. When the result file is stored, the file name under which the test file is stored is generated automatically and can preferably contain the number of the test pass and the calendar week in which the test pass was performed. To improve transparency, the result file can have the computer name or the test system ID as an extension.

If a memory module has errors during a functional test, a log file is automatically generated which contains information about the test, about the test pass, about the errors which have arisen and contains precise data about the error addresses in the memory module. This log file can be contained in the result file.

When the functional tests cited for the memory module or for the memory modules in the test sequence configuration file have been carried out, the test pass is complete.

If errors have been discovered in at least one memory module, these errors are evaluated and the error information is stored in at least one statistic file. In this case, this statistic file advantageously bears the test system ID as an extension. For each test pass, the statistic file is created fresh or is updated. The statistic file has a standard data format with precisely defined contents. It contains information about the test platform and about the memory modules tested and also statistical data about the test sequence, for example, pass/fail information. All the entries in the statistic file can be shown separated from one another by a semicolon, which means that the statistic file can be processed by ordinary spreadsheet programs, particularly, by Microsoft Excel, or by ordinary database programs, particularly by Microsoft Access.

An output unit in the computer system, particularly a screen, then outputs the error information, particularly the log file or the result file containing the log file, and also the statistic file. This information can be used to identify the erroneous memory module or the erroneous memory modules. Such erroneous memory modules can then be marked, in particular, labeled, by a user. Finally, the test system is turned off by the user.

A basic concept of the inventive method is that a specified memory module is tested using test conditions stipulated in a test sequence configuration file, and automatic data conditioning and data logging take place on the basis of the test result. This involves combining identical test conditions and identical test sequences for various memory modules in a test sequence configuration file.

In line with another basic concept of the invention, the inventive method for electronically testing memory modules is not limited to being carried out on a particular computer system, but rather can be carried out on a large number of different computer systems. The properties of the computer system respectively used for testing are covered in the computer system configuration file. This ensures that the inventive method is geared to the respective computer system.

The inventive method is simple to carry out and allows a picture of the reliability of the memory modules to be obtained during the actual manufacturing process for memory modules. The necessary inputs from the user are limited to a few logistical inputs for controlling the test sequence. Provision of the computer system configuration file and of the test sequence configuration files allows different types of memory modules to be tested on different platforms. The test results are available in a precisely defined data format with precisely defined contents, specifically in the form of result files and in the form of a statistic file, as soon as testing has been carried out.

In addition, the inventive method can easily be extended. Thus, the information about the test steps to be performed, which is contained in the test sequence configuration file can easily be changed or extended. New memory modules to be tested can also easily be added thereto. New computer systems for carrying out the inventive test method can easily be provided by using an appropriate configuration of the computer system configuration file.

One advantageous development of the invention includes the inventive method step of inputting production-related data for each memory module connected to the computer system into the computer system, specifically batch numbers, in particular. This step is preferably carried out before the step of electronically reading in the test information from the test sequence configuration file. By recording production-related data, errors detected by the inventive method can be attributed to particular production machines and to particular production times. Such production-related data are advantageously also contained in the result files and statistic files generated in line with the invention.

The invention is also realized in a computer program for carrying out a method for electronically testing at least one memory module detachably connected to a computer system. In this case, the computer program is in a form such that, when one or more test memory modules have been connected to the computer system, the inventive method is realized. In this case, the method can result in a statement being made about whether memory modules are erroneous and, if so, which memory modules are erroneous.

The computer program improved in line with the invention results in an improved check for memory modules, simple and effective error analysis for memory modules, and an improvement in propagation time as compared with the known methods for testing memory modules.

The invention also relates to a computer program that is held on a storage medium, which is stored in a computer memory, which is held in a direct access memory, or which is transmitted on an electric carrier signal.

The invention also relates to a computer program product for carrying out a method for electronically testing memory modules. The invention also relates to a data storage medium holding such a computer program and to a method in which such a computer program is downloaded from an electronic data network, such as the Internet, onto a computer that is connected to the data network.

In line with another aspect of the invention, the inventive method provides a user-friendly interface for performing memory tests, with good documentation of the test results, including a stipulated file format, being provided for reporting.

The computer-implemented, inventive method can be called in various ways, for example, by the user inputting the file name of an executable program into the computer system. It is conceivable for input of the command line argument “i” to cause the current version of the computer-implemented method to be displayed. When the command line argument “q” is input, the user is permitted to input a comment. Inputting the command line argument “v” prompts the inventive method to be carried out in an annotated mode, with a kind of log file being written. When the command line argument “o” is input, the inventive method is carried out in a mode which renames the error file in line with prescribed naming conventions.

An interactive mode for the test sequence can be provided for control purposes. This test sequence can be started by inputting a prescribed character string for the memory module identifier. For such an interactive mode, the keyboard functionality is activated throughout the test sequence. All inputs by the user can also be transferred by command line parameters from other programs to the inventive interface program.

Other features which are considered as characteristic for the invention are set forth in the appended claims.

Although the invention is illustrated and described herein as embodied in a method for electronically testing memory modules, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a flowchart for illustrating the inventive method;

FIG. 2 is a schematic illustration of a memory module test system;

FIG. 3 shows the content of a computer system configuration file;

FIG. 4 shows the content of a test sequence configuration file;

FIG. 5 shows the content of a first result file that has no errors;

FIG. 6 shows the content of a second result file that has an error; and

FIG. 7 shows the content of a statistic file.

### DESCRIPTION OF THE PREFERRED EMBODIMENTS

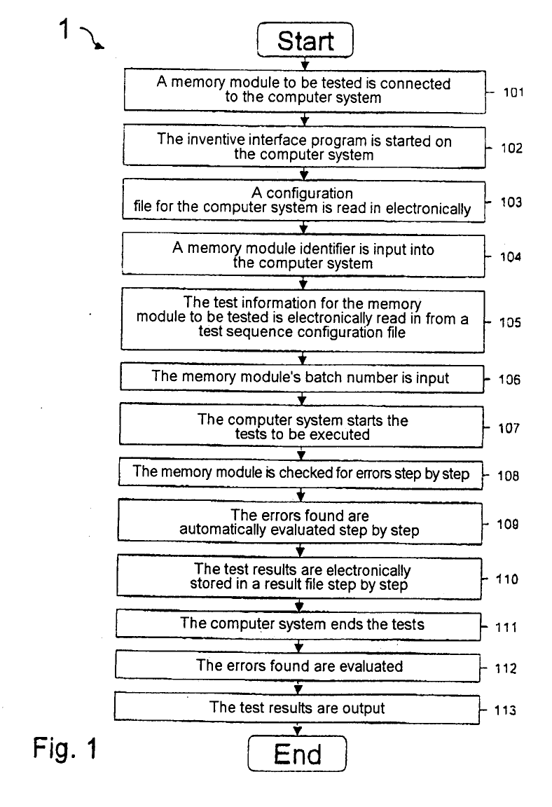

Referring now to the figures of the drawing in detail and first, particularly, to FIG. 1 thereof, there is shown a flowchart 1 for illustrating the inventive method. The flowchart 1 has a total of 13 method steps to be performed in succession. In the first method step 101, a memory module to be tested is connected to the computer system. In the second method step 102, the inventive interface program, which is a computer-implemented form of the inventive method, is started on the computer system. Next, in a third method step 103, a configuration file for the computer system, which is held in a hard disk memory in the computer system, is electronically read into the main memory RAM. In a fourth method step 104, a memory module identifier is then input by a user. In a fifth method step 105, test information for the memory module to be tested is electronically read in from a test sequence configuration file. This test sequence configuration file contains information about the test programs and auxiliary programs which need to be executed in order to test the memory module. In the subsequent, sixth method step 106, the user inputs the memory module's batch number. In the seventh method step 107, the tests and auxiliary programs to be executed are then started by the computer system. This involves sequentially processing test and auxiliary programs, and the memory module is checked for errors step by step in the eighth method step 108. In the ninth method step 109, the errors found are automatically evaluated step by step. In the tenth method step 110, the test results are then electronically stored in a result file step by step. When all the test and auxiliary programs to be executed have been processed, the tests are ended by the computer system in the eleventh method step 111. In the twelfth method step 112, the errors found are be evaluated. The test results are output on the computer system's screen or on a printer in the computer system in the thirteenth method step 113 and these test results are written to a statistic file.

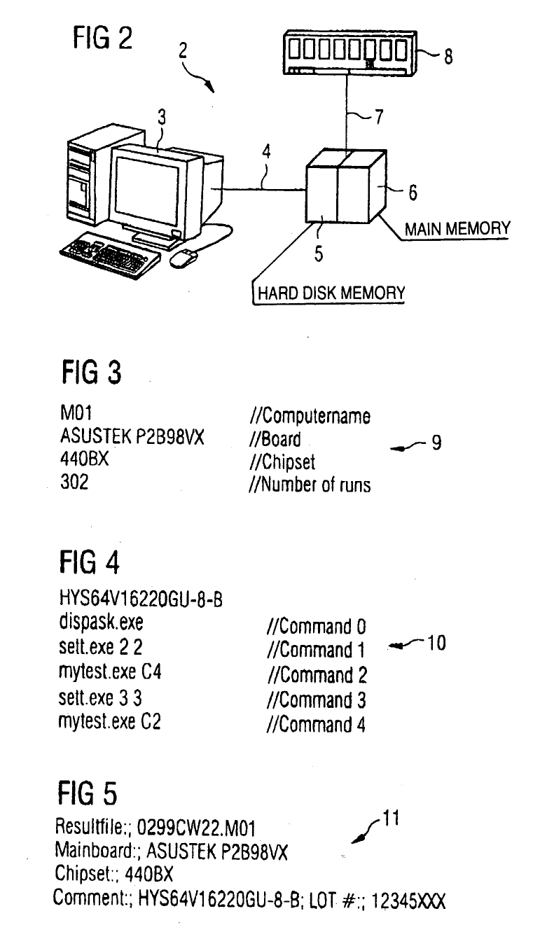

FIG. 2 is a schematic illustration of an exemplary embodiment of a memory module test system 2 with a computer system 3, a first data link 4, a hard disk memory 5, a main memory RAM 6, a second data link 7 and a test memory module 8.

In principle, the main memory RAM 6 can also be the module to be tested if only the lowest megabyte stores the program and the remaining megabytes at the top are tested.

The computer system 3 has a computation unit (not shown in the present case) with at least one processor, at least one input unit, such as a keyboard or a mouse, and at least one output unit, such as a screen or a printer. The computer system 3 is connected to the hard disk memory 5 and to the main memory RAM 6 by the first data link 4. The hard disk memory 5 and the main memory RAM 6, which are shown separately from the computer system 3 in FIG. 2, are often integrated in the computer system 3. If the computer system 3 is in the form of a workstation, for example, the hard disk memory 5 and the main memory RAM 6 are connected to this workstation externally, as shown in FIG. 2.

The test memory module 8 is connected to the computer system 3 or to the hard disk memory 5 and to the main memory RAM 6 by the second data link 7. The test memory module 8 is a memory module of type HYS64V16220GU-8-B. The schematic illustration of the test memory module 8 in FIG. 2 has been greatly simplified.

To perform electronic tests on the test memory module 8, an inventive interface program is provided on the computer system 3. This interface program is the computer-implemented embodiment of the inventive test method. It loads data stored in various files in the hard disk memory 5 into the main memory RAM 6 and uses these data to execute particular test and auxiliary programs in an order which is defined for the test memory module 8. The inventive interface program can be used to check a large number of commercially available memory modules, particularly DIMMs and RIMMs, for errors.

FIG. 3 shows the content of a computer system configuration file 9 in line with the exemplary embodiment.

The computer system configuration file 9 is configured by a user for execution of the inventive interface program. In the present exemplary embodiment, the computer system configuration file 9 is stored in the hard disk memory 5 under the name “PCDATA.DAT”. The first line contains the computer name or the test system ID “M01”. The second line includes the name of the motherboard or of the central board in the computer system 3, which holds all the elements for controlling the connected hardware and peripheral units and for interchanging data with one another. The name of the motherboard is “ASUSTEK P2B98VX” in the present case. The third line shows the chipset, which forms the central element on the motherboard and provides additional influence on the computational power of the computer system 3. In this case, the computational power is determined predominantly by the processor power. It controls the flow of data to the processor and the bus system and is primarily responsible for managing the hard disk memory 5 and the main memory RAM 6. The fourth line of the computer system configuration file 9 contains information about the test passes executed with the computer system 3 hitherto. In the exemplary embodiment, 302 test passes have been executed up to now.

FIG. 4 shows the content of a test sequence configuration file 10 in line with the exemplary embodiment.

The test sequence configuration file 10 shows the test sequence that needs to be executed for the test memory module 8. In this case, it contains executable instructions and programs, particularly test and supplementary programs, which are processed sequentially by the inventive interface program. These instructions and programs are stored in the hard disk memory 5 in the computer system 3, with the exact storage location being ascertainable from the test sequence configuration file 10.

The first line of the test sequence configuration file 10 contains the type designator for the memory test module 8 which is to be tested, namely “HYS64V16220GU-8-B”. The second line contains the first program to be executed by the inventive interface program, namely “dispask.exe”. This auxiliary program requests the memory allocation and the serial number of the connected test memory module 8. The third line contains the call to the auxiliary program which is to be executed, “sett.exe”, which uses special registers to make settings determined-by the chipset, particularly changes to the timing of the test memory module 8. The respective subsequent numerical values “2” are parameters, particularly time constants for this program, which can be altered. The fourth line contains the call “mytest.exe”. This means that a memory test is performed using the test memory module 8. The characters “C4” denote that the memory tests need to be processed by “mytest.exe” four times. The call provided in the fifth line restarts the auxiliary program “sett.exe”, this time with the numerical values “3” as call parameters. The last line of the test sequence configuration file 10 makes the fresh call to the memory test program “mytest.exe”. This time, the tests in this test memory program are performed twice.

The sequence and execution of the aforementioned memory test programs and of the aforementioned auxiliary programs are known to a person skilled in the art and do not need to be explained further at this point.

The test sequence configuration file 10 shown in FIG. 4 is precisely the test sequence which is to be executed for the “HYS64V16220GU-8-B” type of memory modules. The test sequence configuration file 10 is a detail from an overall test sequence configuration file which contains, for a large number of types of test memory modules, the respective test and auxiliary programs which are to be executed. This file combines types of memory modules for which an identical test sequence needs to be executed such that, in a first line, all the type designators for memory modules for which the respectively identical test sequence needs to be executed are listed next to one another. The test and auxiliary programs to be executed are listed in the subsequent lines.

FIG. 5 shows the content of a first result file 11, containing no errors, in line with the exemplary embodiment.

This first result file 11 is generated sequentially, is displayed on the output unit in the computer system 3, particularly on the screen, and is stored in the hard disk memory 5 and/or in the main memory RAM 6. The first result file 11 is named automatically. In the present exemplary embodiment, the name is “0300CW22.M01”. In this case, the first four digits “0300” represent the 300th test pass, and the subsequent digits represent calendar week 22. The extension stored for this first result file 11 is the name of the computer system 3, specifically “M01”.

The second line of the first result file 11 contains the information about the motherboard in the computer system 3. This information matches the information contained in the second line of the computer system configuration file 9. The third line contains the information about the chipset in the computer system 3. This chipset information matches the information contained in the third line of the computer system configuration file 9. The fourth line of the first result file 11 contains a comment about the respective test pass. In the present exemplary embodiment, the comment is divided into the type designator “HYS64V16220GU-8-B” and the batch number “12345XXX” for the test memory module 8. The first result file 11 contains no kind of information about any error which has occurred in the test pass.

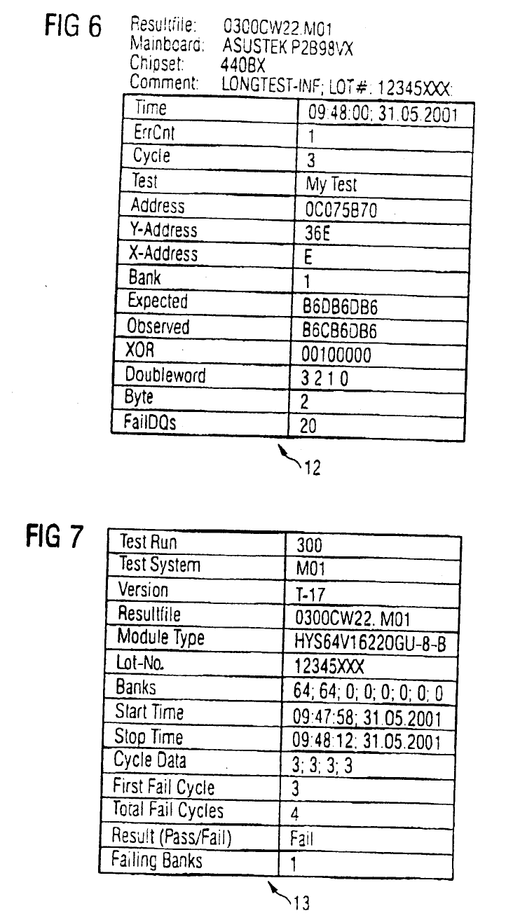

FIG. 6 shows the content of a second result file 12, containing an error, in line with the exemplary embodiment.

The second result file 12 is generated sequentially, is displayed on the output unit in the computer system 3, particularly on the screen, and is stored in the hard disk memory 5 and/or in the main memory RAM 6. It is stored under the name “0300CW22.M01”. The information shown for the file name of the second result file 12, for the main board and for the chipset in the computer system 3 used and for the batch number of the test memory module 8 corresponds to the information shown in FIG. 5 for the first result file 11. The fourth line additionally contains, as a comment, the character string “LONGTEST-INF”, which denotes that the test sequence has been executed in an interactive mode in which the user can make inputs using the keyboard or another input medium for the computer system 3 during the test sequence. This involves the inventive interface program being started and ended interactively.

The second result file 12 additionally has an integrated log file which contains information about an error which occurred when the memory test was performed. The log file contains test and test-pass information and also detailed data about the error addresses.

The data listed in table form in FIG. 6 contains information relating to the test performed and to the errors which have occurred. The memory test was performed at 09:48 on 05.31.2001. The error counter is at “1”, which means that precisely one error has been detected. This error was established in the third memory test performed, namely “MyTest”. This is followed by the processor address “0C075B70”. Next comes the address of the test memory module 8 with the X value “E” and with the Y value “36E”, which can be derived from the processor address. The next item shown is the bank in the computer system 3 with the value “1”. In the case of the present test pass performed, the character string “B6DB6DB6” was expected as the result of the memory test “MyTest”, but the character string “B6CB6DB6” appeared. The comparison between the expected character string and the character string which actually appeared is obtained by forming a difference using the Boolean combinational logic “Exclusive Or” or “XOR”. The character string formed in this manner shows on how many input lines and output lines of the test memory module 8 an error occurs. In the present exemplary embodiment, the character string is “00100000”. This means that an error has occurred on the third input or output line of the test memory module 8. The next row contains the “double word”, specifically the information about whether the upper or lower 4 bytes of the test memory module 8 have been addressed. In this case, it is the lower bytes “3”, “2”, “1” and “0”. The byte which is actually erroneous is byte No “2”. The erroneous input or output line of the test memory module is the one with the number “20”. This is part of byte “2”.

FIG. 7 shows the content of a statistic file 13 in line with the exemplary embodiment.

The statistic file 13 was created after the 300th test pass and logs all test passes performed up to then. The second line contains the information about the computer system used, namely “M01”. The next line contains the information about the version of the inventive interface program used, specifically “T-17”. The next line contains an indication of the last result file generated. In the present case, this is the file name “0300CW22.M01” for the second result file 12. The type designator “HYS64V16220GU-8-B” for the test memory module 8 tested is contained in the next line. The batch number “12345XXX” is obtained from the next line. The total of eight banks of test memory modules 8 are included in the next line. In this case, the first two numerical values “64” in the “banks” line of the statistic file 13 mean that 64 Mbytes of memory have been detected in each of banks “0” and “1”. A subsequent line (not shown in the present case) can include serial numbers. The next two lines respectively record the starting time and the stopping time for the test pass. The next line records the subtests in which the test memory module 8 tested has had operating faults. In the exemplary embodiment, the value 3 is listed four times in this case. This means that the test memory module 8 has failed four times in succession in a respective third subtest. In this context, subtests are respectively understood to mean a memory test which is called by the inventive interface program. The first subtest in which an error was discovered is shown in the next line. This is the third subtest carried out. The total number of subtests carried out in which errors in the test memory module 8 have been discovered are shown in the next line. Errors have shown up in a total of four subtests. The next two lines show the test result “fail” and the bank “1” in which the errors were detected.

At the start of the inventive method, the computer system 3 is configured. This involves a user storing the name of the computer system “M01”, of the motherboard “ASUSTEK P2B98VX” and of the chipset “440BX” in the computer system 3 in the computer system configuration file 9.

In a first method step 101, the computer system 3 is then equipped with the test memory module 8 of type “HYS64V16220GU-8-B”. In the next inventive step, the interface program is started. This can be done by the user or automatically. The computer system configuration file 9 is then read into the main memory RAM 6 in the computer system 3. This file additionally contains a counter for recording the test passes performed on the computer system 3. A product identifier is then input by the user, and is “HYS64V16220GO-8-B” in the present exemplary embodiment. The interface program now establishes whether the product identifier which has been input matches the actual type designator for the test memory module 8. This is so in the present case. The information about the test and the auxiliary programs that need to be executed for the first test memory module 8 is then read in from the test sequence configuration file 10. The user then inputs the batch number for the test memory module 8 into the computer system 3.

The commands, auxiliary programs and test programs contained in the test sequence configuration file 10 are then executed one after the other. In the present exemplary embodiment, the auxiliary programs “dispask.exe” and “sett.exe” are executed first, then a memory test “mytest.exe”, then the auxiliary program “sett.exe” once again, and finally another memory test “mytest.exe”. These are ordinary auxiliary and test programs which are known to a person skilled in the art. They are processed step by step. The test programs are executed step by step, with every test step being followed by a check for errors and by evaluation.

The data generated in this manner are written to result files. A result file generated in this way is the first result file 11. This was generated in the 299th test pass. The name of the computer system 3 used, its main board and its chipset can be seen from this first result file. Similarly, the type designation for the test memory module 8 and the batch number are shown in this first result file 11. This first result file 11 provides no kind of indication of errors which have occurred in this test path.

The second result file 12, shown in FIG. 6, is the second result file 12 generated in the 300th test pass on the computer system 3. This file logs an error which occurred at 09:48 on 05.31.2002. This error was established at the processor address “0C075B70” in the third test pass of the “MyTest” subtest performed. This processor address reveals the error address in the test memory module 8. The error occurred in bank “1” and involved the character string “B6CB6DB6” appearing instead of the expected character string “B6DB6DB6”. This error was established in the second byte of the lower double word and on the 20th input and output line of the test memory module 8.

In the present exemplary embodiment, the instructions prescribed in the test sequence configuration file 10, test and auxiliary programs were ended after execution of the 300th test pass. The errors found were then evaluated and were written to the statistic file 13. This statistic file 13 reveals that an error occurred in the 300th test pass on the test system “M01”. In addition, it contains the name of the second result file 12, which shows further information relating to the error that has occurred. The type designation for the test memory module 8 tested, the batch number and the starting and ending times for this test pass can likewise be found in the statistic file 13. In addition, precise information about the error that has occurred or about the errors which have occurred are included.

This statistic file 13 logs all the test passes and documents the respective error information. The information held in the statistic file 13 is displayed graphically on the screen or on the printer in the computer system 3. This output can be used to establish precisely which test memory modules have failed. These failed modules can be marked by the user and can be taken out of service.

The inventive method outlined for electronically testing memory modules can-be carried out as often as desired in succession for a large number of memory modules. When the test has ended, the computer system 3 is turned off by the user.

We claim:

1. A method for electronically testing one or more memory modules, the method which comprises:
detachably connecting the one or more memory modules to a computer system;
electronically reading a computer system configuration file into the computer system;
for each one of the one or more memory modules connected to the computer system, inputting a respective memory module identifier into the computer system;
electronically comparing a number of the one or more memory modules connected to the computer system with a number of memory module identifiers that have been input;
electronically reading test information for the one or more memory modules into the computer system from at least one test sequence configuration file;
successively and automatically processing test steps in at least one functional test to electronically test the one or more memory modules with the computer system;
successively, electronically storing test results in at least one result file;
automatically evaluating the test results; and
if at least one of the one or more memory modules has errors, then electronically storing error information in at least one statistic file, outputting the error information, and identifying the one or more memory modules that has errors.

2. The method according to claim 1, which comprises after the step of electronically reading the test information, inputting production-related data into the computer system for each of the one or more memory modules.

3. The method according to claim 1, wherein the production-related data are batch numbers.

4. A computer-readable medium having computer-executable instructions for performing a method comprising:
electronically reading a computer system configuration file into a computer system;
for each of one or more memory modules detachably connected to the computer system, inputting a respective memory module identifier into the computer system;
electronically comparing a number of the one or more memory modules connected to the computer system with a number of memory module identifiers that have been input;
electronically reading test information for the one or more memory modules into the computer system from at least one test sequence configuration file;
successively and automatically processing test steps in at least one functional test to electronically test the one or more memory modules with the computer system;
successively, electronically storing test results in at least one result file;
automatically evaluating the test results; and
if at least one of the one or more memory modules has errors, then electronically storing error information in at least one statistic file, outputting the error information, and identifying the one or more memory modules that has errors.

5. The computer-readable medium according to claim 4, wherein the computer-readable medium is a storage medium.

6. The computer-readable medium according to claim 4, wherein the computer-readable medium is a computer memory.

7. The computer-readable medium according to claim 4, wherein the computer-readable medium is a direct access memory.

8. The computer-readable medium according to claim 4, wherein the computer-readable medium is an electric carrier signal.

9. A method, which comprises:
downloading a set of computer-executable instructions from an electronic data network onto a computer connected to the data network;
the computer-executable instructions for performing a method comprising:
electronically reading a computer system configuration file into a computer system,
for each of one or more memory modules detachably connected to the computer system, inputting a respective memory module identifier into the computer system,
electronically comparing a number of the one or more memory modules connected to the computer system with a number of memory module identifiers that have been input,
electronically reading test information for the one or more memory modules into the computer system from at least one test sequence configuration file,
successively and automatically processing test steps in at least one functional test to electronically test the one or more memory modules with the computer system,
successively, electronically storing test results in at least one result file,
automatically evaluating the test results, and
if at least one of the one or more memory modules has errors, then electronically storing error information in at least one statistic file, outputting the error information, and identifying the one or more memory modules that has errors.

10. The method according to claim 9, wherein the electronic data network is an Internet.
